(19) United States
(12) Patent Application Publication
(10) Pub. No.: US 2026/0351918 A1
(43) Pub. Date: Nov. 5, 2026

(54) LASER LIGHT SOURCE, IN PARTICULAR FOR USE IN A MICROLITHOGRAPHIC PROJECTION EXPOSURE SYSTEM

(71) Applicant: Carl Zeiss SMT GmbH, Oberkochen (DE)

(72) Inventors: Nils LUNDT, Ulm (DE); Barbara MOSER, Sontheim an der Brenz (DE); Martin HERMANN, Heidenheim an der Brenz (DE); Conrad WOLKE, Aalen (DE)

(21) Appl. No.: 19/712,803

(22) Filed: Jun. 18, 2026

Related U.S. Application Data
(63) Continuation of application No. PCT/EP2024/086222, filed on Dec. 13, 2024.

(30) Foreign Application Priority Data
Dec. 20, 2023 (DE) 10 2023 135 987.8

(51) Int. Cl. H01S 3/00

(52) U.S. Cl. CPC H01S 3/0057

(57) ABSTRACT

A laser light source comprises: a laser module for generating a multiplicity of light pulses; and an optical pulse stretcher for stretching a pulse length of the light pulses generated by the laser module. The optical pulse stretcher has a plurality of mirrors. Each mirror comprises a mirror substrate and a reflective layer system. At least one of the mirrors has an intermediate layer between mirror substrate and reflective layer system. The intermediate layer forms a diffusion barrier against diffusion of constituents of the reflective layer system to the mirror substrate. The laser light source can be used, for example, in a microlithographic projection exposure apparatus.

### CROSS-REFERENCE TO RELATED APPLICATIONS

The present application is a continuation of, and claims benefit under 35 USC 120 to, international application No. PCT/EP2024/086222, filed Dec. 13, 2024, which claims benefit under 35 USC 119 of German Application No. 10 2023 135 987.8, filed Dec. 20, 2023. The entire disclosure of each of these applications is incorporated by reference herein.

### FIELD

The disclosure relates to a laser light source, for example for use in a microlithographic projection exposure apparatus.

### BACKGROUND

Microlithography is used to produce microstructured electronic components. The microlithography process is carried out in a so-called projection exposure apparatus comprising an illumination device and a projection lens. The image of a mask (=reticle) illuminated using the illumination device is in this case projected using the projection lens onto a substrate (e.g. a silicon wafer) coated with a light-sensitive layer (photoresist) and arranged in the image plane of the projection lens, in order to transfer the mask structure to the light-sensitive coating of the substrate.

In a projection exposure apparatus designed for operation in the DUV range (e.g. at operating wavelengths of less than 250 nm, for example less than 200 nm), use is typically made of laser light sources in the form of excimer lasers, for example krypton fluoride excimer lasers at an operating wavelength of 248 nm or argon fluoride excimer lasers at an operating wavelength of 193 nm.

Existing challenges in the course of the development of projection exposure apparatuses include increasing desired accuracy for microlithographically producing ever smaller structures and positioning them on the wafer and also an increase in the throughput achieved with the respective projection exposure apparatus, this increase being desirable from the standpoint of cost considerations.

As far as the abovementioned increase in the throughput achieved with the respective projection exposure apparatus is concerned, there can be limits imposed on an increase in the pulse energy and/or an increase in the repetition rate, each of these increases being desirable for increasing the output power of the laser light source. The increase in the repetition rate and thus in the frequency of electrical discharges within the resonator of the laser light source, the increase being conceivable for increasing the output power of the laser light source, can lead to acoustic resonances and ultimately to the spectral bandwidth rising above an acceptable measure. On the other hand, an increase in the pulse energy can lead to a higher radiation loading of optical components within the laser light source and also a greater stress for electronic assemblies.

A known approach involves pulses (having a pulse length of e.g. 20 ns) generated by the laser light source being stretched to a longer time duration of e.g. (100-450) ns by using optical pulse stretchers, thereby potentially decreasing the degradation of downstream optical components.

During the operation of such an optical pulse stretcher or a corresponding laser light source, for example when the output power of the laser light source is increased, undesired wavefront aberrations can occur, which can be caused upon passing through the optical pulse stretcher as a result of an undesired change in refractive index of the gas medium near the respective mirror surface of the mirrors heating up as a result of thermal absorption, and which can also be caused by thermally induced deformation or “bulging” of the mirrors themselves. For example, the heating of purge gas (e.g. nitrogen) located in the region of the respective mirror surface can lead to the generation of thermal striations, as a result of which the wavefront of the light that passes through the optical pulse stretcher and is reflected at the relevant mirror can be disturbed. Furthermore, the aforementioned undesired change in refractive index during heating can lead to a thermal lens effect and associated defocusing of the relevant light.

Reference is made merely by way of example to DE 10 2022 202 241 A1 and DE 10 2022 107 633 B3.

### SUMMARY

The present disclosure seeks to provide a laser light source, for example for use in a microlithographic projection exposure apparatus, which makes it possible to increase the output power of the laser light source while avoiding the problems described above, at least to some extent.

In accordance with one aspect of the disclosure, a laser light source, for example for use in a microlithographic projection exposure apparatus, has
a laser module for generating a multiplicity of light pulses; and
an optical pulse stretcher for stretching a pulse length of the light pulses generated by the laser module;
wherein the optical pulse stretcher has a plurality of mirrors each comprising a mirror substrate and a reflective layer system; and
wherein at least one of these mirrors has an intermediate layer between mirror substrate and the reflective layer system, the intermediate layer forming a diffusion barrier against diffusion of constituents of the reflective layer system to the mirror substrate.

By virtue of the fact that an intermediate layer (according to the disclosure e.g. composed of Al₂O₃) is provided between mirror substrate and reflective layer system, the intermediate layer forming a diffusion barrier against diffusion of constituents of the reflective layer system to the mirror substrate, according to the disclosure the choice of the mirror substrate material in the relevant mirror can be made without regard to the materials or constituents present in the reflective layer system in the specific mirror design. For example, since the formation of possibly chemically unstable compounds between constituents of the reflective layer system and constituents of the mirror substrate is in this respect prevented from the outset by the intermediate layer, the risk of potential layer detachments (for instance as a result of undesired formation of gaseous compounds such as e.g. silane) and an associated shortening of the lifetime can also be avoided, which as a result can open up the possibility of using mirror substrate materials which hitherto have been uncommon from the standpoint of lifetime aspects.

In addition to the above-described effect of the intermediate layer which is advantageous from the standpoint of lifetime aspects, a feature is that, from an optical point of view, an undesired effect of any refractive index deviation present between the respective materials of the mirror substrate (according to the disclosure e.g. silicon) and the closest layer ply of the reflective layer system (e.g. lanthanum fluoride) relative to the mirror substrate can be prevented or can be at least mitigated. That is based on the consideration that, in the case of a comparatively high refractive index deviation, the wavelength-dependent profile of the reflectivity R(λ) may otherwise lead in an undesired manner to restriction of the usable wavelength range (i.e. the bandwidth). The intermediate layer provided according to the disclosure and the optical decoupling of mirror substrate and reflective layer system brought about as a result in turn can afford the possibility of making the specific choice of the mirror substrate material without regard to any possible refractive index deviation between the mirror substrate and the closest layer ply of the reflective layer system and thus making possible the choice, rather, from other standpoints—for example for instance the optimization of the adhesion properties in the layer construction, which likewise can open up or expand possibilities for the use of hitherto uncommon mirror substrate materials.

The disclosure includes a deliberate departure from mirror substrate materials that are conventionally customary in an optical pulse stretcher of a laser light source. One conventionally used mirror substrate material is, for example, calcium fluoride (CaF₂), which, owing to its comparatively large energetic band gap and a typically high degree of purity, has a relatively low absorption which is fundamentally advantageous from the standpoint of lifetime aspects.

The disclosure includes configuring, in an optical pulse stretcher of a laser light source, at least one mirror of the optical pulse stretcher with a mirror substrate composed of a mirror substrate material which combines a comparatively low coefficient of thermal expansion of the mirror substrate material with a comparatively high thermal conductivity.

In this case, the mirror substrate material according to the disclosure can be, for example, silicon (Si) in the form of monocrystalline silicon (Si), polycrystalline silicon (Si) or amorphous silicon (Si).

The use according to the disclosure of, for example, silicon (Si) as mirror substrate material, this use not being intuitive against the above background, which material significantly absorbs light passing through the reflective layer system as far as the mirror substrate for instance at the operating wavelengths in the DUV range (e.g. 193 nm) which are especially envisaged according to the disclosure, and which material additionally differs in terms of the coefficient of thermal expansion from the fluoridic materials optionally used in the reflective layer system of the respective mirrors, can now be based on the consideration that, on account of significantly improved heat dissipation in the mirror substrate material according to the disclosure, the disadvantages accepted in general with the omission of a transparent mirror substrate material can be avoided.

In other words, although it is possible to accept according to the disclosure that (residual) light which generally unavoidably passes through the reflective layer system as far as the mirror substrate in the respective mirror is significantly absorbed in the mirror substrate, in return the heat which is consequently generated in the mirror substrate as a result of conversion of the radiation energy can be dissipated comparatively well, as a result of which the wavefront aberrations—mentioned in the introduction—both on account of thermal striation formation and on account of thermally induced mirror deformations can be at least largely avoided. Furthermore, it is possible to accept according to the disclosure that the coefficient of thermal expansion for the silicon (Si) used according to the disclosure as mirror substrate material differs to a comparatively great extent from the coefficient of thermal expansion of the fluoridic materials optionally used in the reflective layer system of the respective mirrors, which can fundamentally result in the formation of thermally induced stresses in the coating process.

The acceptance according to the disclosure of the abovementioned disadvantages is based on the consideration that the thermal conductivity for example of silicon (Si) with a value of approximately 140 W★m⁻¹★K⁻¹ is significantly greater than for instance the thermal conductivity of calcium fluoride (CaF₂) with a value of approximately 9.71 W★m⁻¹★K⁻¹ or the thermal conductivity of quartz glass (SiO₂) with a value of approximately 1.38 W★m⁻¹★K⁻¹. Furthermore, the coefficient of thermal expansion of silicon (Si) with a value of approximately 2.7★10⁻⁶ K⁻¹ is significantly less than the coefficient of thermal expansion of calcium fluoride (CaF₂) with a value of approximately 18.85★10⁻⁶ K⁻¹. The use of silicon as mirror substrate material is furthermore also advantageous with regard to the comparatively high mechanical stability or robustness (the modulus of elasticity of silicon is 97.9 GPa compared to 75.8 GPa for calcium fluoride (CaF₂)).

These properties (i.e. comparatively low coefficient of thermal expansion, high mechanical stability and comparatively high thermal conductivity) can each be advantageous with regard to the sought minimization of the local thermal bulging or the mirror heating (and the associated striation formation and the thermal lens effect).

For the aforementioned quartz glass (SiO₂), although the coefficient of thermal expansion with a value of approximately 0.5★10⁻⁶ K⁻¹ is even lower than for the silicon (Si) used according to the disclosure as mirror substrate material, for quartz glass (SiO₂) as mirror substrate material the mirror temperature is increased owing to the abovementioned comparatively low thermal conductivity relative to the silicon (Si) used according to the disclosure, which in turn has a disadvantageous effect on the contributions to wavefront aberrations discussed in the introduction, namely thermally induced local mirror deformations and thermal striation formation.

A concept according to the disclosure of using for example silicon (Si) as mirror substrate material has the further advantage that, owing to the particularly efficient dissipation of heat, it is possible to dispense with comparatively complex active cooling of the relevant mirror (and associated cooling fluid connections, cooling fluid channels, etc.). Furthermore, according to the disclosure, desired properties with regard to conventionally customary directional cooling via a directed gas flow can also be relaxed, in which case, as described below, such directional cooling can also be totally avoided without losses, if appropriate, in embodiments of the disclosure.

A further advantage can be that the concept according to the disclosure can be realized in laser light sources of existing (e.g. lithography) systems without significant adaptations.

Further advantages of the use of, for example, silicon (Si) as mirror substrate material can result from the high availability and the relatively low material costs (for instance in comparison with the use of calcium fluoride as mirror substrate material), and from the comparatively good processability from the standpoint of manufacturing aspects.

In accordance with one embodiment, the intermediate layer is produced from Al₂O₃ or SiO₂.

In accordance with one embodiment, the material of the intermediate layer is selected from the group containing Al, Ag, Ba, Ca, Cd, Ce, Co, Cs, Dy, Er, Eu, Fe, Ga, Gd, Hf, Ho, In, Ir, K, La, Li, Lu, Mg, Mn, Na, Nb, Nd, Ni, Os, Pb, Pd, Pr, Rb, Re, Rh, Ru, Sc, Sm, Sn, Sr, Ta, Tb, Ti, Tl, Tm, W, Y, Yb, Zn, Zr and the above materials in oxidized or fluorinated form.

In accordance with one embodiment, the intermediate layer has a thickness of at least 5 nm, for example in the range of 5 nm to 50 nm.

In accordance with one embodiment, the mirror substrate substantially consists of a material from the group containing Si, Ge, C, SiC, BN, AlN, GaN, InN, GaP, InP, AlAs, GaAs, InAs, GaSb, AlF₃, BaF₂, GaF₃, GdF₃, InF₃, KF, MgF₂, ScF₃, TaF₅, YF₃, MgO, Al₂O₃, Y₃Al₅O₁₂, GdScO₃, YAlO₃ and KTaO₃.

In accordance with a further aspect of the disclosure, a laser light source, for example for use in a microlithographic projection exposure apparatus, has
a laser module for generating a multiplicity of light pulses; and
an optical pulse stretcher for stretching a pulse length of the light pulses generated by the laser module;
wherein the optical pulse stretcher has a plurality of mirrors each comprising a mirror substrate and a reflective layer system; and
wherein the mirror substrate of at least one of these mirrors is produced from silicon (Si).

In accordance with a further aspect of the disclosure, the mirror substrate of at least two, for example of at least three, more particularly of all, mirrors of the optical pulse stretcher is produced in each case from silicon (Si).

In accordance with a further aspect of the disclosure, a laser light source, for example for use in a microlithographic projection exposure apparatus, has
a laser module for generating a multiplicity of light pulses; and
an optical pulse stretcher for stretching a pulse length of the light pulses generated by the laser module;
wherein the optical pulse stretcher has a plurality of mirrors each comprising a mirror substrate and a reflective layer system; and
wherein the mirror substrate of at least one of these mirrors is produced from a material from the group containing BaF₂, MgF₂, MgO, Al₂O₃ and KTaO₃.

The mirror substrate materials mentioned above (i.e. BaF₂, MgF₂, MgO, Al₂O₃ and KTaO₃) can be distinguished by the fact that an intermediate layer for avoiding a reaction from constituents of firstly the reflective layer system and secondly the mirror substrate can optionally also be dispensed with, without a risk of layer detachments arising.

In accordance with one embodiment, at least some of the mirrors of the optical pulse stretcher are arranged in positions offset with respect to one another relative to the direction of gravity, wherein the at least one mirror is arranged in the last of these positions relative to the direction of gravity.

For a mirror of the optical pulse stretcher situated in this position, the configuration according to the disclosure with a mirror substrate composed of, for example, silicon (Si) can be particularly advantageous insofar as the problem solved according to the disclosure, inter alia, of the (purge) gas heating for this mirror is particularly serious in view of the gas possibly ascending and thus reaching the rest of the optically used region of the optical pulse stretcher.

In further embodiments, the at least one mirror produced for example with silicon (Si) as substrate material can also be in each case a concave mirror with a concavely curved optical effective surface facing in the direction of gravity. For a mirror arranged in this way, possibly heated gas in the region of the optical effective surface cannot escape, or can escape only with difficulty, without additional purging, so that the advantageous effect achieved according to the disclosure pertaining to avoiding such heating is manifested to a particular degree here as well.

In accordance with one embodiment, the reflective layer system of the at least one mirror has a multilayer construction composed of a plurality of individual layers, wherein the number of these individual layers is at least twenty, for example at least thirty, more particularly at least forty, and more particularly at least fifty. These individual layers can be layers of individual layer stacks or else functional layers (e.g. in the form of barrier layers or adhesion layers).

In accordance with one embodiment, the reflective layer system of the at least one mirror has a transmittance of less than 3%, for example less than 2%, more particularly less than 1%.

In the abovementioned configurations with a comparatively large number of individual layers in the multilayer construction or a comparatively low transmittance of the reflective layer system, the absorbing property of the mirror substrate material used according to the disclosure can be additionally accommodated by virtue of a reduction in the proportion of light passing through the reflective layer system as far as the mirror substrate. In a further embodiment, in addition or as an alternative to a comparatively large number of individual layers in the multilayer construction, an absorbent layer in the form of a substrate protection layer or a corresponding absorbent layer system can also be provided in the layer construction.

In accordance with one embodiment, the reflective layer system of the at least one mirror has a reflectivity of at least 98% over a spectral bandwidth of at least 10 nm.

In accordance with one embodiment, the at least one mirror has an optical effective surface, wherein at least one surface normal to this optical effective surface is arranged at an angle in the range of 80° to 100°, for example at an angle in the range of 85° to 95°, more particularly at an angle of 90°, with respect to the direction of gravity.

For such a mirror arranged with its optical effective surface substantially “vertically” (i.e. not “in a horizontal position”), it can hold true that an issue addressed with conventional directional cooling via a directed gas flow in the case of mirrors arranged substantially “horizontally” or “in a horizontal position”, namely the deposition of particles on the optical effective surface of the mirror, is greatly reduced, so that the omission according to the disclosure of such directional cooling with a directed gas flow can be effected without losses overall.

In accordance with one embodiment, the optical pulse stretcher is arranged in such a way that an angle between the light entrance direction into the optical pulse stretcher and the direction of gravity is in the range of 85° to 95°.

In accordance with one embodiment, the optical pulse stretcher has an output power of more than 1 watt (W), for example of more than 10 watts (W), more particularly of more than 40 watts (W).

For such high output powers of the optical pulse stretcher, the thermal issues described in the introduction can be particularly relevant, and so the advantages of the configuration according to the disclosure of the optical pulse stretcher, owing to the configuration of one or more mirrors with, for example, silicon (Si) as mirror substrate material, can then be also manifested to a particular degree.

In accordance with one embodiment, the optical pulse stretcher is designed to stretch light pulses generated by the laser module in the laser light source and having a pulse length of at least 20 nanoseconds (ns) to a pulse length of at least 100 nanoseconds (ns).

In accordance with one embodiment, the optical pulse stretcher is designed to stretch light pulses generated by the laser module in the laser light source and having a pulse length of at least 20 ns to a pulse length of less than 10,000 ns, for example of less than 1000 ns, more particularly of less than 750 ns.

In accordance with one embodiment, the laser light source is designed for an operating wavelength of less than 360 nm, for example for an operating wavelength of less than 250 nm, more particularly for an operating wavelength of less than 200 nm.

In accordance with one embodiment, the laser light source is designed for an operating wavelength of more than 120 nm, for example more than 150 nm.

The disclosure provides a microlithographic projection exposure apparatus, comprising a laser light source, an illumination device and a projection lens, wherein during operation of the projection exposure apparatus, the illumination device illuminates an object plane of the projection lens with light from the laser light source and the projection lens images this object plane onto an image plane, wherein the laser light source is configured in accordance with the features described above.

Further configurations of the disclosure can be gathered from the description and the dependent claims.

The disclosure is explained in greater detail below on the basis of exemplary embodiments illustrated in the accompanying figures.

### BRIEF DESCRIPTION OF THE DRAWINGS

In the drawings:

FIG. 1 shows a schematic illustration for explaining the possible basic construction of a laser light source according to the disclosure;

FIG. 2A shows a schematic illustration for explaining the possible construction of one mirror present in an optical pulse stretcher of a laser light source according to the disclosure;

FIG. 2B shows a schematic illustration for explaining the possible construction of a further mirror present in an optical pulse stretcher of a laser light source according to the disclosure;

FIG. 3 shows a schematic illustration for explaining the possible basic construction of a laser light source according to the disclosure in a further embodiment; and

FIG. 4 shows a schematic illustration for explaining the possible construction of a microlithographic projection exposure apparatus designed for operation in the DUV.

### DETAILED DESCRIPTION

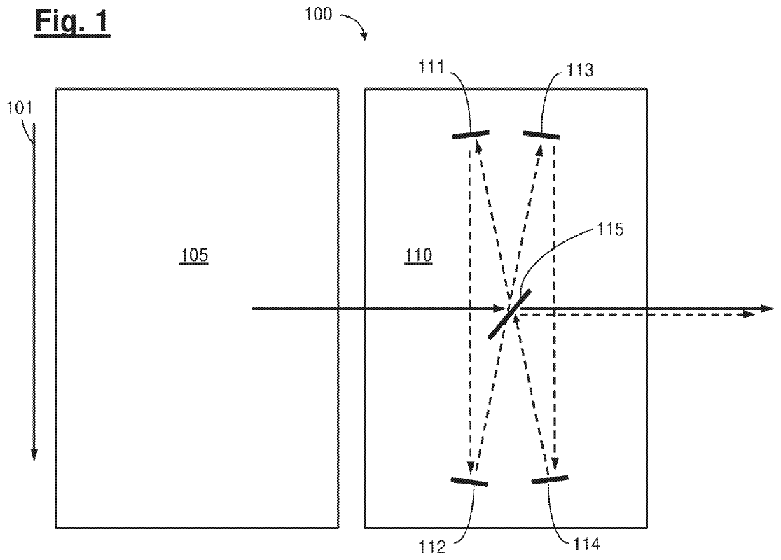

Embodiments of the present disclosure are explained below with reference to the schematic illustrations in FIGS. 1-3.

FIG. 1 firstly shows a schematic illustration of the possible basic construction of a laser light source 100 according to the disclosure. The laser light source 100 has a laser module 105, indicated merely schematically and configured in a conventional manner per se, for generating a multiplicity of light pulses. These light pulses can each have a pulse length of the order of magnitude of 30 nanoseconds (ns) merely by way of example (and without the disclosure being restricted thereto) and enter an optical pulse stretcher designated by “110”. The optical pulse stretcher 110 has a beam splitter 115 and a plurality of mirrors 111-114, only four mirrors of which are depicted in FIG. 1 for the sake of simplicity. The disclosure is not restricted to a specific number of mirrors within the optical pulse stretcher, wherein in embodiments this number of mirrors can be typically eight to twelve merely by way of example. The direction of gravity is designated by the arrow “101”.

As a consequence of the repeated reflection of the light component output coupled by the beam splitter 115 (dashed arrows) at the respective optical effective surfaces of the mirrors 111-114, as indicated in FIG. 1, this output coupled light component experiences a temporal delay in a manner known per se in relation to the light component transmitted through the beam splitter 115 before the output coupled light component follows the transmitted light component following reflection at the beam splitter 115. The temporal stretching achieved overall can be effected here in a conventional manner by disposing in series a plurality of stages according to this principle with different propagation time delays in each case. For the sake of simplicity, only two beams emerging from the optical pulse stretcher 110 are depicted in the schematic illustration in FIG. 1, although the number of circulations or partial beams can be significantly higher in practice.

Merely by way of example (and without the disclosure being restricted thereto), it is possible to implement the stretching of the pulse length achieved in the optical pulse stretcher 110 to a pulse length in the range of 100 nanoseconds (ns) to 750 nanoseconds (ns).

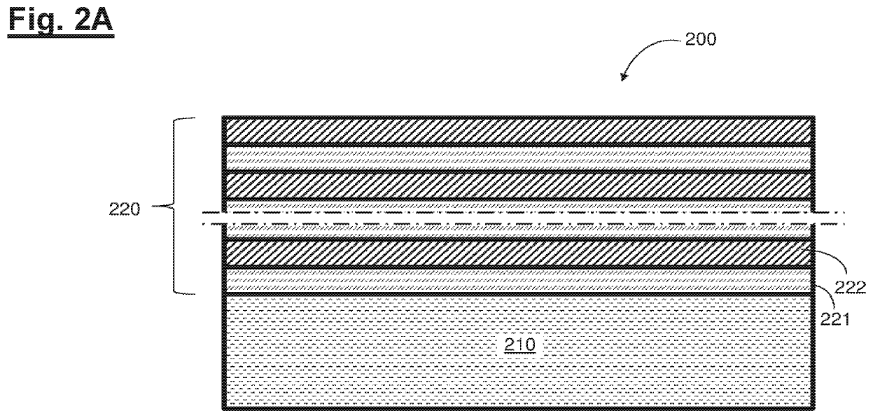

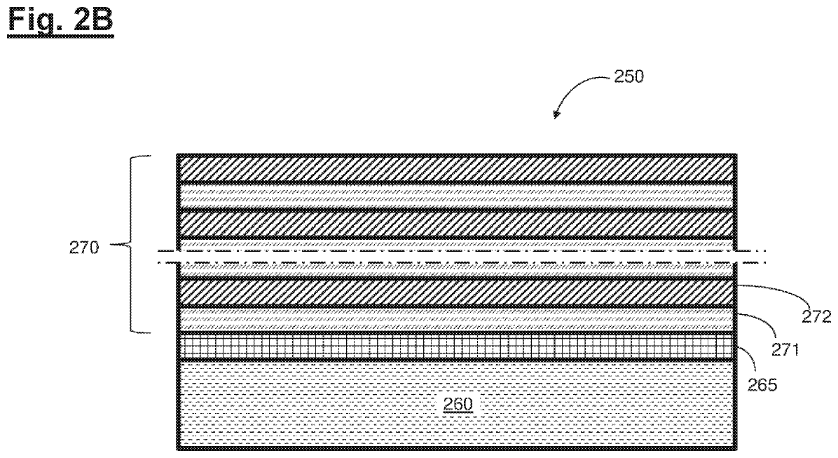

FIG. 2A shows a schematic illustration for explaining one possible exemplary embodiment of a mirror 200 in the optical pulse stretcher 110 of a laser light source 100 according to the disclosure. The mirror 200 according to the disclosure in accordance with FIG. 2A has a mirror substrate 210 and a reflective layer system 220, wherein further functional layers (not illustrated) e.g. in the form of barrier layers or adhesion layers can additionally also be provided in the layer construction of the mirror 200.

In a multilayer construction, the reflective layer system 220 has a plurality of alternately arranged individual layers 221, 222, wherein these individual layers can comprise a fluoridic material for example in a manner known per se. This can be, for example, for example aluminum fluoride (AlF₃), gadolinium fluoride (GdF₃), lanthanum fluoride (LaF₃), magnesium fluoride (MgF₂), sodium aluminum fluoride (NaAlF₃) or ytterbium fluoride (YbF₃).

The number of individual layers is typically (without the disclosure being restricted thereto) at least twenty, and in embodiments of the disclosure can be at least thirty, more particularly at least forty, and more particularly at least fifty. These individual layers can be layers of individual layer stacks or else functional layers (e.g. in the form of barrier layers or adhesion layers).

FIG. 2B shows a schematic illustration for explaining a further exemplary embodiment of a mirror in the optical pulse stretcher 110 of a laser light source 100 according to the disclosure. Components that are analogous or substantially functionally identical in comparison with FIG. 2A are designated here by reference numerals increased by “50”. The mirror in accordance with FIG. 2B has an intermediate layer 265 between mirror substrate 260 and reflective layer system 270, the intermediate layer forming a diffusion barrier against diffusion of constituents of the reflective layer system 270 to the mirror substrate 260. The intermediate layer 265 can for example have a thickness of at least 5 nm, for example in the range of 5 nm to 50 nm, and be produced from Al₂O₃ or SiO₂. In further embodiments, the material of the intermediate layer is selected from the group containing Al, Ag, Ba, Ca, Cd, Ce, Co, Cs, Dy, Er, Eu, Fe, Ga, Gd, Hf, Ho, In, Ir, K, La, Li, Lu, Mg, Mn, Na, Nb, Nd, Ni, Os, Pb, Pd, Pr, Rb, Re, Rh, Ru, Sc, Sm, Sn, Sr, Ta, Tb, Ti, Tl, Tm, W, Y, Yb, Zn, Zr and the above materials in oxidized or fluorinated form.

The at least one mirror 200 (in accordance with FIG. 2A) or 250 (in accordance with FIG. 2B) provided according to the disclosure in the optical pulse stretcher of the laser light source 100 is distinguished for example by the fact that what is used as mirror substrate material of the mirror substrate 210, 260 is a different material than is conventionally customary in an optical pulse stretcher of a laser light source (one conventionally used mirror substrate material being calcium fluoride (CaF₂), for example).

As a result—in addition to further advantages already discussed above—for example a significant reduction in wavefront aberrations is achieved by virtue of the occurrence of the disturbance factors of thermally induced local mirror deformations and thermal striation formation, as likewise already discussed in the introduction, being reduced.

Wavefront experiments carried out by the inventors show that the local thermally induced deformation or bulging for example for silicon (Si) as mirror substrate material is significantly reduced in comparison, for instance, with calcium fluoride (CaF₂) as mirror substrate material when irradiated with laser light having an operating wavelength of approximately 193 nm. In the wavefront experiments, the surface of the respective samples was scanned with a laser beam of 633 nm and the wavefront of the light reflected at the respective sample was measured with a wavefront sensor. Despite the comparatively greater total absorption (approximately 0.2%) of the sample produced from silicon (Si) in comparison with the total absorption of the sample produced from calcium fluoride (CaF₂) (approximately 0.1%), a significantly smaller thermally induced deformation or bulging is observed for the silicon (Si) sample. In the experiment, the PV value (peak-to-valley; indicated in each case in arbitrary units, a.u.) of 3.9 for the calcium fluoride (CaF₂) sample was reduced to a PV value of 0.43 for the silicon (Si) sample.

As a consequence of the presence of the intermediate layer 265 in the layer construction of the mirror 250 in accordance with FIG. 2B, the choice of the mirror substrate material in respect of the substrate 260 can be made without regard to the materials or constituents present in the reflective layer system 270. This is because owing to the diffusion barrier provided by the intermediate layer 265, formation of possibly chemically unstable compounds between constituents of the reflective layer system 270 and constituents of the mirror substrate 260 is prevented from the outset, such that potential layer detachments and an associated shortening of the lifetime are also avoided. Moreover, from an optical point of view, too, an undesired effect of any refractive index deviation present between the respective materials of mirror substrate 260 and the closest layer ply of the reflective layer system 270 relative to the mirror substrate 260 can be prevented or at least mitigated.

In accordance with FIG. 2A, the mirror substrate 210 can be produced from a material from the group containing BaF₂, MgF₂, MgO, Al₂O₃ and KTaO₃. The mirror substrate materials mentioned above (i.e. BaF₂, MgF₂, MgO, Al₂O₃ and KTaO₃) are distinguished by the fact that an intermediate layer for avoiding a reaction from constituents of firstly the reflective layer system and secondly the mirror substrate can optionally also be dispensed with, without a risk of layer detachments arising.

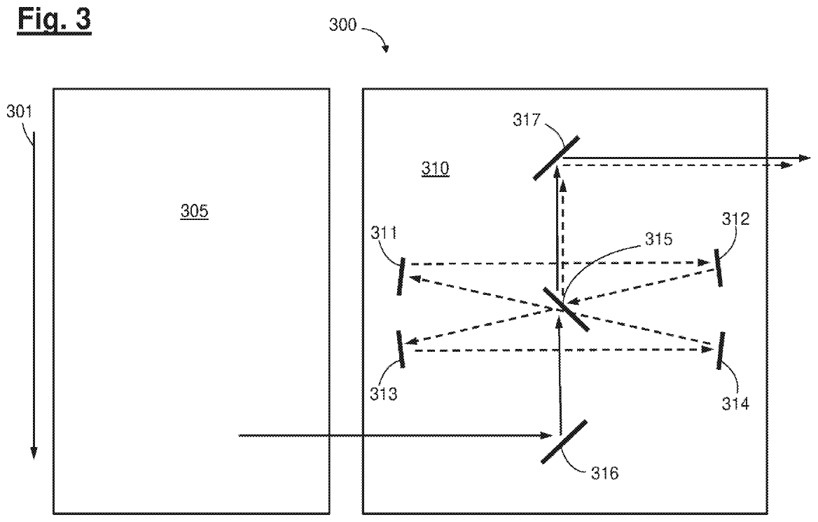

FIG. 3 shows a schematic illustration for explaining the possible basic construction of a laser light source according to the disclosure in a further embodiment, wherein analogous or substantially functionally identical components in comparison with FIG. 1 are designated by reference numerals increased by “200”. In this case, in accordance with FIG. 3, the optical pulse stretcher 310 is rotated by 90° in comparison with FIG. 1, which is achieved in accordance with FIG. 3 merely by way of example using two additional deflection mirrors 316, 317 in the optical beam path. As a consequence of this arrangement, the mirrors 311-314 in the optical pulse stretcher 310 are arranged with their respective optical effective surface substantially “vertically” (i.e. not “in a horizontal position”). This has the consequence that a problem solved with conventional directional cooling via a directed gas flow in the case of mirrors arranged substantially “horizontally” or “in a horizontal position”, namely the deposition of particles on the optical effective surface of the mirror, is greatly reduced, so that the omission according to the disclosure of such directional cooling with a directed gas flow can be effected without losses overall.

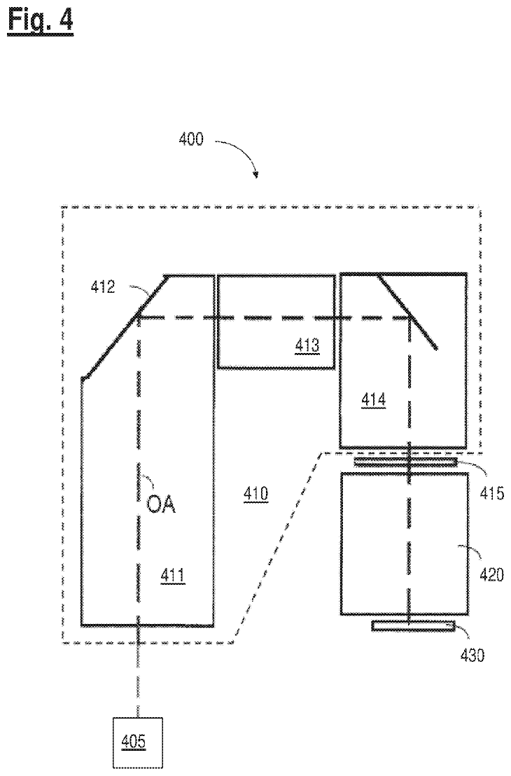

FIG. 4 shows a construction—possible in principle—of a microlithographic projection exposure apparatus 400 designed for operation in the DUV as an application example of a laser light source according to the disclosure.

The projection exposure apparatus 400 in accordance with FIG. 4 has an illumination device 410 and a projection lens 420. The illumination device 410 serves for illuminating a structure-bearing mask (reticle) 415 with light from a light source unit 405 comprising a laser light source for example in the form of an ArF excimer laser for an operating wavelength of approximately 193 nm (or else in the form of an XeF excimer laser for an operating wavelength of approximately 351 nm, in the form of a KrF excimer laser for an operating wavelength of approximately 248 nm or in the form of an F₂ excimer laser for an operating wavelength of approximately 157 nm) and also a beam shaping optical unit that generates a parallel light beam.

The illumination device 410 has an optical unit 411 which, inter alia, comprises a deflection mirror 412 in the example illustrated. The optical unit 411 can have for example a diffractive optical element (DOE) and a zoom-axicon system for producing different illumination settings (i.e. intensity distributions in a pupil plane of the illumination device 410). A light mixing device (not illustrated) is situated in the beam path downstream of the optical unit 411 in the light propagation direction, which light mixing device can e.g. have, in a manner known per se, an arrangement composed of micro-optical elements which is suitable for attaining light mixing, and a lens-element group 413, downstream of which there is a field plane with a reticle masking system (REMA), which is imaged by a REMA lens 414, disposed downstream in the light propagation direction, onto the structure-bearing mask (reticle) 415 arranged in a further field plane and which thereby delimits the illuminated region on the reticle. The structure-bearing mask 415 is imaged by the projection lens 420 onto a lens element substrate or a wafer 430 provided with a light-sensitive layer (photoresist). For example, the projection lens 420 can be designed for immersion operation, in which case an immersion medium is situated upstream of the wafer, or the light-sensitive layer thereof, relative to the light propagation direction. Furthermore, it can have for example a numerical aperture NA of greater than 0.85, for example greater than 1.1.

Even though the disclosure has been described on the basis of specific embodiments, numerous variations and alternative embodiments are evident to a person skilled in the art, e.g. through combination and/or exchange of features of individual embodiments. Accordingly, it goes without saying for a person skilled in the art that such variations and alternative embodiments are also encompassed by the present disclosure, and the scope of the disclosure is restricted only within the meaning of the accompanying patent claims and the equivalents thereof.

What is claimed is:

1. A laser light source, comprising:
a laser module configured to generate a multiplicity of light pulses; and
an optical pulse stretcher configured to stretch a pulse length of the light pulses generated by the laser module,
wherein:
the optical pulse stretcher comprises a plurality of mirrors;
each mirror of the plurality of mirrors comprises a mirror substrate and a reflective layer system;
the plurality of mirrors comprises a first mirror;
the first mirror comprises an intermediate layer between its mirror substrate and its reflective layer system; and
the intermediate layer defines a barrier against diffusion of constituents of the reflective layer system to the mirror substrate.

2. The laser light of claim 1, wherein the intermediate layer comprises a member selected from the group consisting of Al₂O₃ and SiO₂.

3. The laser light source of claim 1, wherein the intermediate layer comprises a member selected from the group consisting of Al, Ag, Ba, Ca, Cd, Ce, Co, Cs, Dy, Er, Eu, Fe, Ga, Gd, Hf, Ho, In, Ir, K, La, Li, Lu, Mg, Mn, Na, Nb, Nd, Ni, Os, Pb, Pd, Pr, Rb, Re, Rh, Ru, Sc, Sm, Sn, Sr, Ta, Tb, Ti, Tl, Tm, W, Y, Yb, Zn, Zr, oxides thereof, and fluorides thereof.

4. The laser light source of claim 1, wherein the intermediate layer is at least five nanometers thick.

5. The laser light source of claim 1, wherein the mirror substrate consists essentially of a member selected from the group consisting of Si, Ge, C, SiC, BN, AlN, GaN, InN, GaP, InP, AlAs, GaAs, InAs, GaSb, AlF₃, BaF₂, GaF₃, GdF₃, InF₃, KF, MgF₂, ScF₃, TaF₅, YF₃, MgO, Al₂O₃, Y₃Al₅O₁₂, GdScO₃, YAlO₃ and KTaO₃.

6. The laser light source of claim 1, wherein at least some of the mirrors of the plurality of mirrors are offset with respect to one another relative to a direction of gravity, and the first mirror is in a last position relative to the direction of gravity.

7. The laser light source of claim 1, wherein the reflective layer system of the first mirror comprises at least 20 individual layers.

8. The laser light source of claim 1, wherein the reflective layer system of the first mirror has a transmittance of less than 3%.

9. The laser light source of claim 1, wherein the reflective layer system of the first mirror has a reflectivity of at least 98% over a spectral bandwidth of at least 10 nanometers.

10. The laser light source of claim 1, wherein the first mirror comprises an optical effective surface disposed at an angle of from 80° to 100° relative to a direction of gravity.

11. The laser light source of claim 1, wherein the optical pulse stretcher is configured so that an angle between a light entrance direction into the optical pulse stretcher and a direction of gravity is from 85° to 95°.

12. The laser light source of claim 1, wherein the optical pulse stretcher has an output power of more than one watt.

13. The laser light source of claim 1, wherein the optical pulse stretcher is configured to stretch light pulses having a pulse length of from 20 nanoseconds to 100 nanoseconds.

14. The laser light source of claim 1, wherein the optical pulse stretcher is configured to stretch light pulses having a pulse length of from 20 nanoseconds to 10,000 nanoseconds.

15. The laser light source of claim 1, wherein the laser light source is configured to operate at a wavelength of less than 360 nanometers.

16. The laser light source of claim 15, wherein the laser light source is configured to operate at a wavelength of more than 120 nanometers.

17. The laser light source of claim 1, wherein the laser light source is configured to operate at a wavelength of more than 120 nanometers.

18. An apparatus, comprising:
a laser light source according to claim 1;
an illumination device; and
a projection lens,
wherein:
the illumination device is configured to illuminate an object plane of the projection lens with light from the laser light source;
the projection lens is configured to image the object plane onto an image plane; and
the apparatus is a microlithographic projection exposure apparatus.

19. A laser light source, comprising:
a laser module configured to generate a multiplicity of light pulses; and
an optical pulse stretcher configured to stretch a pulse length of the light pulses generated by the laser module,
wherein:
the optical pulse stretcher comprises a plurality of mirrors;
each of the plurality of mirrors comprises a mirror substrate and a reflective layer system;
the plurality of mirrors comprises a first mirror;
the mirror substrate of the first mirror comprises a member selected from the group consisting of AlF₃, BaF₂, GaF₃, GdF₃, InF₃, KF, MgF₂, ScF₃, TaF₅, YF₃, MgO, Al₂O₃ and KTaO₃.

20. An apparatus, comprising:
a laser light source according to claim 19;
an illumination device; and
a projection lens,
wherein:
the illumination device is configured to illuminate an object plane of the projection lens with light from the laser light source;
the projection lens is configured to image the object plane onto an image plane; and
the apparatus is a microlithographic projection exposure apparatus.
